(19) United States
(12) Patent Application Publication
(10) Pub. No.: US 2019/0324569 A1
(43) Pub. Date: Oct. 24, 2019

(54) TOUCH DISPLAY PANEL, METHOD FOR DRIVING THE SAME, AND TOUCH DISPLAY DEVICE

(71) Applicants: BOE Technology Group Co., Ltd., Beijing (CN); Chengdu BOE Optoelectronics Technology Co., Ltd., Chengdu (CN)

(72) Inventors: Guoqiang MA, Beijing (CN); Yingsong XU, Beijing (CN); Yang WANG, Beijing (CN); Guoqiang TANG, Beijing (CN); Yuanyuan CHAI, Beijing (CN); Kuo SUN, Beijing (CN); Yangpeng WANG, Beijing (CN); Yao HU, Beijing (CN)

(21) Appl. No.: 16/199,452

(22) Filed: Nov. 26, 2018

(30) Foreign Application Priority Data
Apr. 23, 2018 (CN) 201810367124.1

(51) Int. Cl. G06F 3/042; H01L 41/047; G06F 3/041

(52) U.S. Cl. CPC G06F 3/042; G06F 3/0412; H01L 41/047

(57) ABSTRACT

Disclosed are a touch display panel, a method for driving the same, and a touch display device. The touch display panel includes: an base substrate; and a touch structure arranged above the base substrate, wherein the touch structure includes a first electrode layer and a second electrode layer arranged at different layers, and transparent piezoelectric elements arranged in an array between the first electrode layer and the second electrode layer; wherein at least one of the first electrode layer and the second electrode layer includes electrode elements arranged in an array, and the transparent piezoelectric elements are configured to filter light.

### CROSS-REFERENCE TO RELATED APPLICATION

This application claims priority of Chinese Patent Application No. 201810367124.1, filed on Apr. 23, 2018, which is hereby incorporated by reference in its entirety.

### FIELD

The present disclosure relates to the field of touch display technologies, and particularly to a touch display panel, a method for driving the same, and a touch display device.

### BACKGROUND

The finger recognition technologies are advancing rapidly, and evolving into products, and they include ultrasonic recognition, optical recognition, capacitive recognition, etc.

### SUMMARY

An embodiment of the disclosure provides a touch display panel including:

a base substrate; and

a touch structure arranged above the base substrate, wherein the touch structure includes a first electrode layer and a second electrode layer arranged at different layers, and transparent piezoelectric elements arranged in an array between the first electrode layer and the second electrode layer;

wherein at least one of the first electrode layer and the second electrode layer includes electrode elements arranged in an array, and the transparent piezoelectric elements are configured to filter light.

In a possible implementation, in the touch display panel above according to the embodiment of the disclosure, the touch display panel further includes:

light-emitting elements and an encapsulation film layer arranged between the base substrate and the touch structure successively; and

the transparent piezoelectric elements are arranged corresponding to the light-emitting elements in a one-to-one manner.

In a possible implementation, in the touch display panel above according to the embodiment of the disclosure, the light-emitting elements include red light-emitting elements, green light-emitting elements, and blue light-emitting elements; and

the transparent piezoelectric elements include first transparent piezoelectric elements which can filter red light, second transparent piezoelectric elements which can filter green light, and third transparent piezoelectric elements which can filter blue light;

wherein projections of the first transparent piezoelectric elements and the red light-emitting elements onto the base substrate overlap, projections of the second transparent piezoelectric elements and the green light-emitting elements onto the base substrate overlap, and projections of the third transparent piezoelectric elements and the blue light-emitting elements onto the base substrate overlap.

In a possible implementation, in the touch display panel above according to the embodiment of the disclosure, the first electrode layer includes the electrode elements arranged in an array, and the second electrode layer is an integral electrode structure; and

the first electrode layer is arranged between the transparent piezoelectric elements and the encapsulation film layer.

In a possible implementation, in the touch display panel above according to the embodiment of the disclosure, the electrode elements are arranged corresponding to the light-emitting elements in a one-to-one manner.

In a possible implementation, in the touch display panel above according to the embodiment of the disclosure, orthographic projections of the light-emitting elements onto the base substrate lie into orthographic projections of the electrode elements onto the base substrate.

In a possible implementation, in the touch display panel above according to the embodiment of the disclosure, the touch display panel further includes:

black matrixes arranged between the transparent piezoelectric elements; and

orthographic projections of the black matrixes onto the base substrate do not overlap with orthographic projections of the light-emitting elements onto the base substrate.

In a possible implementation, in the touch display panel above according to the embodiment of the disclosure, the touch display panel further includes:

a glass cover plate arranged above the touch structure.

In a possible implementation, in the touch display panel above according to the embodiment of the disclosure, the material of the transparent piezoelectric elements is organic polyvinylidene fluoride and pigment materials.

Correspondingly an embodiment of the disclosure further provides a touch display device including the touch display panel according to any one of the embodiments of the disclosure.

Correspondingly an embodiment of the disclosure further provides a method for driving a touch display panel, the method including:

supplying the first electrode layer and the second electrode layer respectively with a touch detection driving signal and a voltage signal;

receiving a sensed touch signal fed back by the first electrode layer or the second electrode layer after a user touches the touch display panel; and

determining the position of the touch by the user according to the sensed touch signal, or determining fingerprint information of the user at the position of the touch according to a variation of the sensed touch signal.

### BRIEF DESCRIPTION OF THE DRAWINGS

FIG. 1 is a schematic structural diagram of a touch display panel in the related art.

FIG. 2A to FIG. 2C are schematic structural diagrams respectively of a touch display panel according to an embodiment of the disclosure.

FIG. 3 is a schematic structural diagram of a light-emitting element according to an embodiment of the disclosure.

FIG. 4 is a second schematic structural diagram of the touch display panel according to the embodiment of the disclosure.

FIG. 5 is a schematic diagram of light rays reflected on the touch display panel according to the embodiment of the disclosure.

FIG. 6 is a schematic structural diagram of a touch detection and fingerprint recognition circuit in the touch display panel according to the embodiment of the disclosure.

FIG. 7 is a third schematic structural diagram of the touch display panel according to the embodiment of the disclosure.

FIG. 8 is a fourth schematic structural diagram of the touch display panel according to the embodiment of the disclosure.

FIG. 9 is a schematic flow chart of a method for driving a touch display panel according to an embodiment of the disclosure.

### DETAILED DESCRIPTION OF THE EMBODIMENTS

In order to make the objects, features, and advantages above of the disclosure more apparent and readily understood, the disclosure will be described below in further details with reference to the drawings and the embodiments thereof. However the exemplary embodiments can be implemented in a number of forms, but shall not be construed as being limited to the embodiments described here; and on the contrary, these embodiments are provided to make the disclosure of the disclosure more full and complete, and to completely convey the idea of the embodiments to those skilled in the art. Like reference numerals in the drawings denote identical or like structures, so a repeated description thereof will be omitted. All the terms as described in the disclosure to represent positions and directions will be described by way of an example with reference to the drawings, but can also be varied as needed without departing from the scope of the disclosure as claimed. The drawings of the disclosure are merely intended to illustrate relative positional relationships, and the thicknesses of some components may be exaggerated in the drawings for the sake of convenient understanding, but the thicknesses in the drawings may not suggest any proportional relationship between the real thicknesses.

It shall be noted that particular details will be set forth in the following description to facilitate full understanding of the disclosure. However the disclosure can be embodied in a number of other embodiments than those described here, and those skilled in the art can generalize them without departing from the spirit of the disclosure. Accordingly the disclosure will not be limited to the particular embodiments to be disclosed below. For example, some words may be used in the description and the claims to refer to specific components. Those skilled in the art shall appreciate that hardware manufacturers may denominate the same component using different names. In the description and the claims, the components will not be distinguished using their different names, but will be distinguished using their different functions. For example, “include” or “comprise” or a variant thereof as referred to throughout the description and the claims is an open term, and thus shall be construed as “include but will not be limited to”. Preferred embodiments of the disclosure will be described below merely for the purpose of setting forth the general principle of the disclosure, but not for limiting the scope of the disclosure thereto. The scope of the disclosure as claimed shall be as defined in the appended claims. It shall be appreciated that if one element, e.g., a layer, a film, an area, or a substrate, is referred to as being “on” another element, then the element may be directly on the other element, or there may be one or more elements arranged between them.

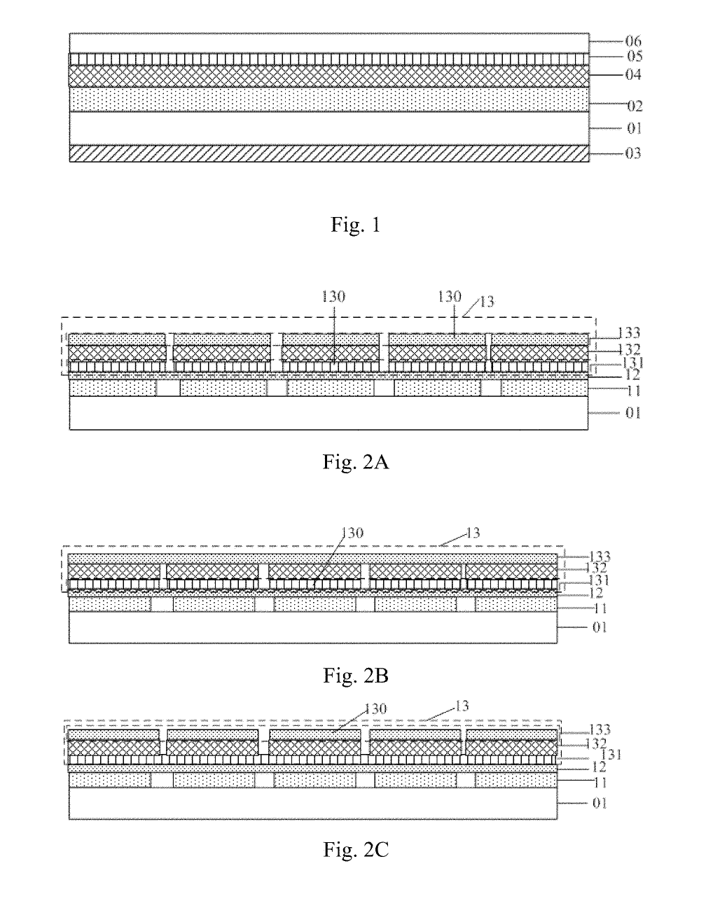

When a common ultrasonic fingerprint recognition device is arranged in a display panel, it is generally attached thereto, and as illustrated in FIG. 1, an Active Matrix/Organic

Light-Emitting Diode (AMOLED) display panel includes: an array substrate 01, a light-emitting structure 02 and a fingerprint recognition structure 03 arranged on two sides of the array substrate 01, and a touch screen 04, a polarizing sheet 05, and a cover plate 06 arranged on the side of the light-emitting structure 02 away from the array substrate 01 successively, where the polarizing sheet 05 shall be adhered to the cover plate 06 using an Optically Clear Adhesive (OCA), and the touch screen 04 shall be adhered to the light-emitting structure 02 using the optically clear adhesive, thus increasing the thickness of the touch display panel, and thus the bending radius of the touch display panel fabricated.

In view of this, in order to address the problem above, embodiments of the disclosure provide a touch display panel, a method for driving the same, and a touch display device so as to dispense with a polarizing sheet in the touch display panel so as to reduce the thickness of the touch display panel, and the bending radius of the touch display panel.

Implementations of the touch display panel, the method for driving the same, and the touch display device according to the embodiments of the disclosure will be described below in details with reference to the drawings.

The thicknesses and shapes of respective layers in the drawings are not intended to reflect any real proportion, but only intended to illustrate the disclosure of the disclosure.

Referring to FIG. 2A, FIG. 2B, or FIG. 2C, a touch display panel according to an embodiment of the disclosure includes: a base substrate 01, and a touch structure 13 arranged above the base substrate 01; and the touch structure 13 includes a first electrode layer 131, a second electrode layer 133, and transparent piezoelectric elements 132 arranged in an array between the first electrode layer 131 and the second electrode layer 132, and the transparent piezoelectric elements 132 can filter light, where as illustrated in FIG. 2A, both the first electrode layer 131 and the second electrode layer 133 include electrode elements 130 arranged in an array; or as illustrated in FIG. 2B, the first electrode layer 131 includes electrode elements 130 arranged in an array, and the second electrode layer 133 is an integral electrode; or as illustrated in Fig.2C, the second electrode layer 133 includes electrode elements 130 arranged in an array, and the first electrode layer 131 is an integral electrode.

It shall be noted that both the first electrode layer and the second electrode layer in the embodiment of the disclosure are transparent electrodes, and different voltage is applied to the first electrode layer and the second electrode layer so that the transparent piezoelectric element vibrate and generate an ultrasonic signal, and then the first electrode layer or the second electrode layer detects the ultrasonic signal fed back by a user to detect a touch and to recognize a fingerprint.

Optionally, in the embodiment of the disclosure, the transparent piezoelectric elements which can filter light are arranged in the touch structure, so that the touch structure capable of detecting a touch and recognizing a fingerprint can also act as a polarizing sheet to filter light, thus dispensing with a polarizing sheet in the touch display panel, and reducing the thickness and the bending radius of the touch display panel.

In an optional implementation, in the touch display panel above according to the embodiment of the disclosure, as illustrated in FIG. 2A, FIG. 2B, or FIG. 2C, the touch display panel further includes: light-emitting elements 11 arranged between the base substrate 01 and the touch structure 13, and an encapsulation film layer 12 arranged above the light-emitting elements 11, where the transparent piezoelectric elements 132 are arranged corresponding to the light-emitting elements 11 in a one-to-one manner.

It shall be noted that FIG. 2A, FIG. 2B, or FIG. 2C only illustrates the first electrode layer arranged between the transparent piezoelectric elements 132 and the encapsulation film layer 12 by way of an example, but the embodiment of the disclosure will not be limited to the structure as illustrated in FIG. 2A, FIG. 2B, or FIG. 2C. Of course, alternatively the second electrode layer 133 can be arranged between the transparent piezoelectric elements 132 and the encapsulation film layer 12, and the first electrode layer 131 can be arranged on the side of the transparent piezoelectric elements 132 away from the base substrate 10.

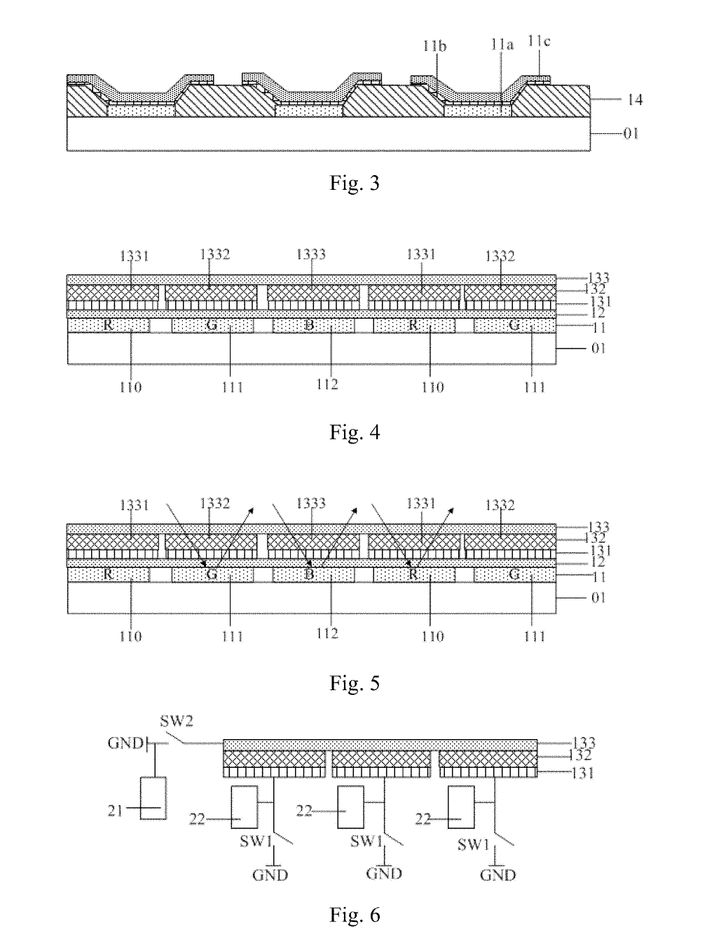

In an optional implementation, as illustrated in FIG. 3, each of the light-emitting elements in the touch display panel include a cathode 11a, a light-emitting layer 11b, and an anode 11c arranged above the base substrate 01 successively. The light-emitting layer can be made of an organic material with a low molecular weight, or a macromolecule material, and the light-emitting layer includes an organic emitting layer, and can further include at least one of a Hole Injection Layer (HIL), a Hole Transmission Layer (HTL), an Electron Transmission Layer (ETL), and an Electron Injection Layer (EIL); and the anode and the cathode can be transparent electrodes or reflecting electrodes. When the anode is a transparent electrode, the transparent electrode can be made of indium tin oxide (ITO), indium zinc oxide (IZO), zinc oxide (Zn0), indium oxide (In₂O₃), etc.; when the anode is a reflecting electrode, a reflecting layer can be made of one or a mixture of Ag, Mg, Al, Pt, Pd, Au, Ni, Nd, Ir, and Cr, and ITO, IZO, ZnO, In₂O₃, etc., can be formed on the reflecting layer; when the cathode is a transparent electrode, the transparent electrode can be made of one or a compound of Li, Ca, LiF or CaF, LiF or AlF, Al, and Mg, where the material can be initially deposited on the light-emitting layer through vaporization, and the material of the transparent electrode made of ITO, IZO, ZnO, In₂O₃, etc., for example, can be deposited on the compound; and when the cathode is a reflecting electrode, the cathode can be formed by vaporizing one or a mixture of Li, Ca, LiF or CaF, LiF or AlF, Al, and Mg throughout the surface of the substrate. Optionally, the touch display panel further a pixel definition layer 14 arranged between the cathodes 11a and the light-emitting layers 11b. The pixel definition layer 14 is an integral structure, and the cathodes 11a cover a part of the pixel definition layer 14.

In order to drive the light-emitting elements in the touch display panel to emit light for displaying an image, the touch display panel further includes a driving layer, configured to drive the light-emitting elements, between the base substrate and the light-emitting elements, where the driving layer includes a driving circuit including a plurality of thin film transistors. Since the driving circuit is structured as in the related art, a repeated description thereof will be omitted here.

In an optional embodiment, the cathodes or the anodes in the light-emitting elements can be reflecting electrodes, and in order to avoid the reflecting electrodes in the light-emitting elements from hindering an image from being displayed normally on the display panel, an upper polarizing sheet shall be arranged to deflect or filter and thus eliminate natural light reflected by the light-emitting elements. In the touch display panel above according to the embodiment of the disclosure, the light-emitting elements include red light-emitting elements, green light-emitting elements, and blue light-emitting elements; and the transparent piezoelectric elements include first transparent piezoelectric elements which can filter red light, second transparent piezoelectric elements which can filter green light, and third transparent piezoelectric elements which can filter blue light, where projections of the first transparent piezoelectric elements and the red light-emitting elements onto the base substrate overlap, projections of the second transparent piezoelectric elements and the green light-emitting elements onto the base substrate overlap, and projections of the third transparent piezoelectric elements and the blue light-emitting elements onto the base substrate overlap. Referring to FIG. 4, for example, the light-emitting elements 11 include red light-emitting elements 110, green light-emitting elements 111, and blue light-emitting elements 112 arranged in an array; and the transparent piezoelectric elements 132 include first transparent piezoelectric elements 1331, second transparent piezoelectric elements 1332, and third transparent piezoelectric elements 1333, where the first transparent piezoelectric elements 1331 are arranged corresponding to the red light-emitting elements 110 in a one-to-one manner, second transparent piezoelectric elements 1332 are arranged corresponding to the green light-emitting elements 1111 in a one-to-one manner, and third transparent piezoelectric elements 1333 are arranged corresponding to the blue light-emitting elements 112 in a one-to-one manner. Optionally, the first transparent piezoelectric elements can filter red light, and absorb green and blue light rays, and filter red light rays; the second transparent piezoelectric elements can filter green light, and absorb red and blue light rays, and filter green light rays; and the third transparent piezoelectric can filter blue light, and absorb red and green light rays, and filter blue light rays. According in the embodiment of the disclosure, red light rays reflected by the red light-emitting elements are filtered by the first transparent piezoelectric elements, and thus cut down, green light rays reflected by the green light-emitting elements are filtered by the second transparent piezoelectric elements, and thus cut down, and blue light rays reflected by the blue light-emitting elements are filtered by the third transparent piezoelectric elements, and thus cut down.

The transparent piezoelectric elements in the embodiment of the disclosure can filter light similarly to a color filter layer in a color filter layer; and as illustrated in FIG. 5, natural light is incident on the touch display panel from the outside, and since the natural light can be filtered by the transparent piezoelectric elements by a factor of approximately 67% (for example, blue and green light rays are absorbed by the first transparent piezoelectric elements), and the remaining natural light of approximately 33% is incident on the touch display panel. Since the touch display panel generally has an opening ratio of approximately 20%, the natural light of approximately 6.6% is reflected by the reflecting electrodes in the light-emitting elements, and thus an influence of the light-emitting elements can be alleviated.

In an optional embodiment, in the touch display panel above according to the embodiment of the disclosure, the material of the transparent piezoelectric elements includes organic polyvinylidene fluoride (PVDF) and pigment materials. The transparent piezoelectric elements in the embodiment of the disclosure generate an ultrasonic signal under the action of voltage between two upper and lower electrode layers of the transparent piezoelectric elements, and feed the ultrasonic signal back to the electrode elements, and the electrode elements detect the position of a touch, and a fingerprint of a touching user. Optionally, the transparent piezoelectric elements can be made of organic polyvinylidene fluoride, and in order to act as a color filter sheet, the transparent piezoelectric elements can further include a red pigment material, a green pigment material, and a blue pigment material. Of course, another transparent material(s) can be further added to the transparent piezoelectric elements, although the embodiment of the disclosure will not be limited thereto. Optionally, the transparent piezoelectric elements can be formed by coating an organic polyvinylidene fluoride layer, and adding the pigment materials to the respective transparent piezoelectric elements.

In an optional embodiment, in the touch display panel above according to the embodiment of the disclosure, in order to perform a touch detection function and a fingerprint recognition function, the first electrode layer or the second electrode layer includes electrode elements arranged in an array, and as illustrated in FIG. 2A or FIG. 2B, the first electrode layer 131 includes electrode elements 130 arranged in an array, and the first electrode layer 131 is arranged between the transparent piezoelectric elements 132 and the encapsulation film layer 12. The electrode elements at the first electrode layer function as detection driving electrodes. The second layer is arranged on the side of the transparent piezoelectric elements away from the encapsulation film layer, and the second electrode layer can include electrode elements arranged in an array as illustrated in FIG. 2A, or the second electrode layer is an integral electrode structure as illustrated in FIG. 2B. The second electrode layer is a common electrode.

In order to detect a touch, the ultrasonic signal is reflected back to the touch structure after the user touches the touch display panel, so in order to detect the ultrasonic signal which is fed back, generally the first electrode layer in the embodiment of the disclosure is a detecting electrode, and the second electrode layer is a driving electrode; or the first electrode layer is a detection driving electrode, and the second electrode layer is a common electrode, although the embodiment of the disclosure will not be limited thereto.

Optionally, in the embodiment of the disclosure, in order for the transparent piezoelectric elements to detect a touch, and to recognize a fingerprint, an Integrated Circuit (IC) arranged in a bezel area of the touch display panel provides the electrode elements at the first electrode layer, and the second electrode layer respectively with a touch detection driving signal and a voltage signal in a touch detection stage so that the transparent piezoelectric elements vibrate and generate an ultrasonic signal under the action of the difference in voltage between the first electrode layer and the second electrode layer, and when the user touches the display panel, the ultrasonic signal is reflected to a part of the electrode elements at the first electrode layer; and the IC determines the position of the touch by the user according to a received sensed touch signal fed back by an electrode element. The Integrated Circuit (IC) arranged in the bezel area of the touch display panel provides the electrode elements at the first electrode layer, and the second electrode layer respectively with a touch detection driving signal and a voltage signal in a fingerprint recognition stage so that the transparent piezoelectric elements vibrate and generate an ultrasonic signal under the action of the difference in voltage between the first electrode layer and the second electrode layer, and when the user touches the display panel, the ultrasonic signal is reflected to a part of the electrode elements at the first electrode layer; and the IC determines a variation of a received sensed fingerprint recognition signal fed back by an electrode element according to the sensed fingerprint recognition signal to thereby determine the positions of valleys and ridges of a finger of the user. Particularly the touch detection driving signal and the fingerprint recognition driving signal may or may not be the same signal, although the embodiment of the disclosure will not be limited thereto.

Optionally, the touch display panel includes a display area and a bezel area, both the light-emitting elements and the touch structure in the embodiment of the disclosure are located in the display area, the IC is located in the bezel area of the touch display panel, and the bezel area further includes first touch leads for electrically connecting the electrode elements with the IC, and second touch leads for electrically connecting the second electrode layer with the IC. Since the second electrode layer is an integral electrode, the number of second touch leads is at least one, and the number of first touch leads is the same as the number of electrode elements. It shall be noted that if the second electrode layer includes a plurality of electrode elements, then the number of second touch leads will be the same as the number of electrode elements at the second electrode layer. Optionally, in order to illustrate a scheme diagram of the touch detection and fingerprint recognition circuit in further details, as illustrated in FIG. 6, in the touch detection driving stage, a second switch element SW2 is opened, a first switch element SW1 is closed, the IC provides the second electrode layer 133 with a touch detection driving signal through a driving circuit 21, and the first electrode layer 131 with a voltage signal through the first switch element SW1, and the transparent piezoelectric element 132 vibrates and generates an ultrasonic signal; and when the user touch the display panel, a part of the ultrasonic signal is fed back to a part of the electrode elements at the first electrode layer 131. In the touch detection stage or the fingerprint recognition stage, the second switch element SW2 is closed, the first switch element SW1 is opened, an ultrasonic signal fed back to the first electrode layer is fed back to the IC through the detection circuit, and the IC calculates and determines the position of the touch, and the valley and the ridges of the fingerprint according to the ultrasonic signal which is fed back.

In an optional embodiment, in the touch display panel above according to the embodiment of the disclosure, both the first electrode layer and the second electrode layer are transparent electrodes, and the transparent piezoelectric elements are arranged corresponding to the light-emitting elements in a one-to-one manner; and in order to drive the transparent piezoelectric elements respectively, the electrode elements 130 at the first electrode layer 131 are arranged corresponding to the light-emitting elements 11 in a one-to-one manner as illustrated in FIG. 2B; or the electrode elements 130 at both the first electrode layer 131 and the second electrode layer 133 are arranged corresponding to the light-emitting elements 11 in a one-to-one manner.

Optionally, an orthographic projection of each electrode element onto the base substrate overlaps with an orthographic projection of a light-emitting element corresponding to the electrode element onto the base substrate, or an orthographic projection of a light-emitting element onto the base substrate lies into an orthographic projection of an electrode element corresponding to the light-emitting element onto the base substrate.

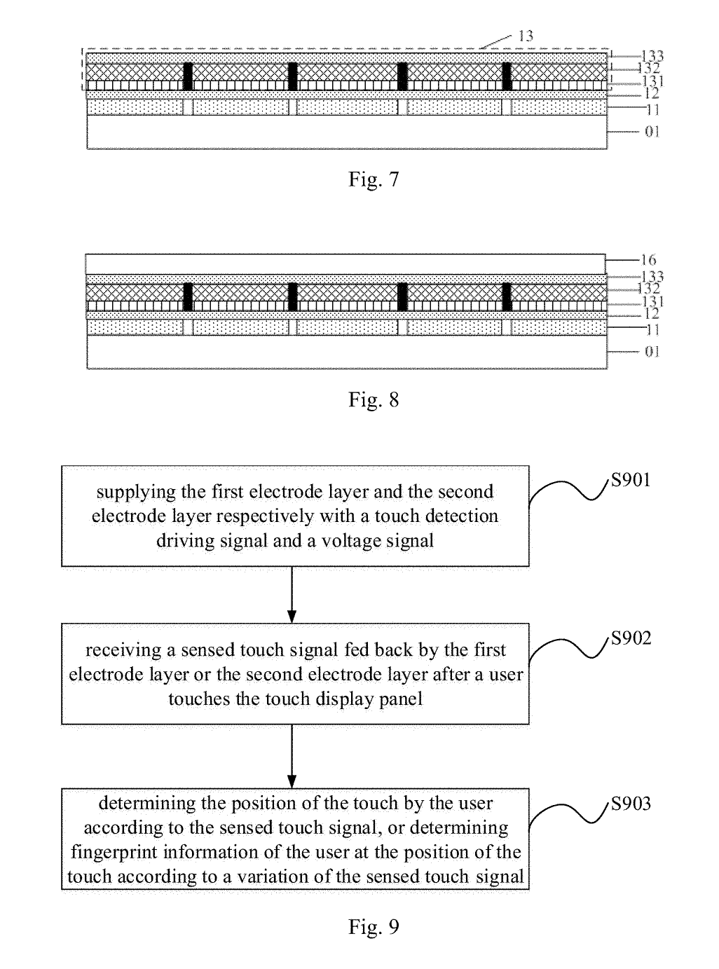

In an optional embodiment, in the touch display panel above according to the embodiment of the disclosure, as illustrated in FIG. 7, the touch display panel further includes: black matrixes 15 arranged between the transparent piezoelectric elements 132, where orthographic projections of the black matrixes onto the base substrate do not overlap with orthographic projections of the light-emitting elements 11 onto the base substrate. Optionally, in order to avoid light of the light-emitting elements in the touch display panel from being leaked, the black matrixes are arranged between the transparent piezoelectric elements; and since the transparent piezoelectric elements are arranged corresponding to the light-emitting elements in a one-to-one manner, the black matrixes do not overlap with the light-emitting elements, where the light-emitting element in the touch display panel include anodes, light-emitting layers, and cathodes; and the touch display panel further includes pixel definition layers arranged between the light-emitting layers and the cathodes, a part of the pixel definition layers are not covered with the light-emitting layers, and in the embodiment of the disclosure, projections of the black matrixes, and the pixel definition layers which are not covered with the light-emitting layers, onto the base substrate overlap with each other.

In an optional embodiment, in the touch display panel above according to the embodiment of the disclosure, as illustrated in FIG. 8, the touch display panel further includes: a glass cover plate 16 arranged above the touch structure. Optionally, in the embodiment of the disclosure, the pigment materials are formed in the transparent piezoelectric elements instead of a polarizing sheet, so as compared with the related art, a polarizing sheet is dispensed with, and also the step of adhering a polarizing sheet with the glass cover plate using an OCA is dispensed with, in the embodiment of the disclosure to thereby further reduce the thickness of the OCA, and the thickness of the touch display panel. The glass cover plate in the embodiment of the disclosure can protect the touch display panel.

Based upon the same inventive idea, an embodiment of the disclosure further provides a touch display device including the touch display panel according to any one of the embodiments above of the disclosure. Particular implementations and advantageous effects of the touch display device according to the embodiment of the disclosure are the same as the touch display panel above, so a repeated description thereof will be omitted here.

Based upon the same inventive idea, referring to FIG. 9, an embodiment of the disclosure further provides a method for driving the touch display panel, where the method includes the following steps.

The step S901 is to supply the first electrode layer and the second electrode layer respectively with a touch detection driving signal and a voltage signal.

The step S902 is to receive a sensed touch signal fed back by the first electrode layer or the second electrode layer after a user touches the touch display panel.

The step S903 is to determine the position of the touch by the user according to the sensed touch signal, or to determine fingerprint information of the user at the position of the touch according to a variation of the sensed touch signal.

Optionally, determining the fingerprint information of the user at the position of the touch includes determining the positions of valleys and ridges in a fingerprint of the user at the touch position according to the variation of the sensed touch signal to determine the fingerprint information of the user.

Optionally, a touch can be detected, and a fingerprint can be recognized in the method for driving the touch display panel according to the embodiment of the disclosure in the same way as the operating principle of detecting a touch and recognizing a fingerprint as described in the touch display panel according to the embodiment of the disclosure, so a repeated description thereof will be omitted here.

In summary, the touch display panel according to the embodiment of the disclosure includes: an base substrate, and a touch structure arranged above the base substrate; and the touch structure includes a first electrode layer and a second electrode layer arranged at different layers, and transparent piezoelectric elements arranged in an array between the first electrode layer and the second electrode layer, where the first electrode layer and/or the second electrode layer includes electrode elements arranged in an array, and the transparent piezoelectric elements can filter light. Accordingly in the touch display panel according to the embodiment of the disclosure, the transparent piezoelectric elements which can filter light are arranged in the touch structure, so that the touch structure is capable of detecting a touch, recognizing a fingerprint, and filtering light, thus further dispensing with a polarizing sheet in the touch display panel, and further reducing the thickness of the touch display panel, and the bending radius of the touch display panel.

Evidently those skilled in the art can make various modifications and variations to the disclosure without departing from the spirit and scope of the disclosure. Thus the disclosure is also intended to encompass these modifications and variations thereto so long as the modifications and variations come into the scope of the claims appended to the disclosure and their equivalents.

1. A touch display panel, comprising:
a base substrate; and
a touch structure arranged above the base substrate, wherein the touch structure comprises a first electrode layer and a second electrode layer arranged at different layers, and transparent piezoelectric elements arranged in an array between the first electrode layer and the second electrode layer;
wherein at least one of the first electrode layer and the second electrode layer comprise electrode elements arranged in an array, and the transparent piezoelectric elements are configured to filter light.

2. The touch display panel according to claim 1, further comprises:
light-emitting elements and an encapsulation film layer arranged between the base substrate and the touch structure successively; and
the transparent piezoelectric elements are arranged corresponding to the light-emitting elements in a one-to-one manner.

3. The touch display panel according to claim 2, wherein:
the light-emitting elements comprise red light-emitting elements, green light-emitting elements, and blue light-emitting elements; and
the transparent piezoelectric elements comprise first transparent piezoelectric elements which can filter red light, second transparent piezoelectric elements which can filter green light, and third transparent piezoelectric elements which can filter blue light;
wherein projections of the first transparent piezoelectric elements and the red light-emitting elements onto the base substrate overlap, projections of the second transparent piezoelectric elements and the green light-emitting elements onto the base substrate overlap, and projections of the third transparent piezoelectric elements and the blue light-emitting elements onto the base substrate overlap.

4. The touch display panel according to claim 2, wherein the first electrode layer comprises the electrode elements arranged in an array, and the second electrode layer is an integral electrode structure; and
the first electrode layer is arranged between the transparent piezoelectric elements and the encapsulation film layer.

5. The touch display panel according to claim 2, wherein the electrode elements are arranged corresponding to the light-emitting elements in a one-to-one manner.

6. The touch display panel according to claim 5, wherein orthographic projections of the light-emitting elements onto the base substrate lie into orthographic projections of the electrode elements onto the base substrate.

7. The touch display panel according to claim 2, further comprises:
black matrixes arranged between the transparent piezoelectric elements; and
orthographic projections of the black matrixes onto the base substrate do not overlap with orthographic projections of the light-emitting elements onto the base substrate.

8. The touch display panel according to claim 1, further comprises:
a glass cover plate arranged above the touch structure.

9. The touch display panel according to claim 1, wherein the material of the transparent piezoelectric elements is organic polyvinylidene fluoride and pigment materials.

10. A touch display device, comprising the touch display panel according to claim 1.

11. The touch display device touch display panel according to claim 10, wherein the touch display panel further comprises:
light-emitting elements and an encapsulation film layer arranged between the base substrate and the touch structure successively; and
the transparent piezoelectric elements are arranged corresponding to the light-emitting elements in a one-to-one manner.

12. The touch display device according to claim 11, wherein:
the light-emitting elements comprise red light-emitting elements, green light-emitting elements, and blue light-emitting elements; and
the transparent piezoelectric elements comprise first transparent piezoelectric elements which can filter red light, second transparent piezoelectric elements which can filter green light, and third transparent piezoelectric elements which can filter blue light;
wherein projections of the first transparent piezoelectric elements and the red light-emitting elements onto the base substrate overlap, projections of the second transparent piezoelectric elements and the green light-emitting elements onto the base substrate overlap, and projections of the third transparent piezoelectric elements and the blue light-emitting elements onto the base substrate overlap.

13. The touch display device according to claim 11, wherein the first electrode layer comprises the electrode elements arranged in an array, and the second electrode layer is an integral electrode structure; and
the first electrode layer is arranged between the transparent piezoelectric elements and the encapsulation film layer.

14. The touch display device according to claim 11, wherein the electrode elements are arranged corresponding to the light-emitting elements in a one-to-one manner.

15. The touch display device according to claim 14, wherein orthographic projections of the light-emitting elements onto the base substrate lie into orthographic projections of the electrode elements onto the base substrate.

16. The touch display device according to claim 11, wherein the touch display panel further comprises:
black matrixes arranged between the transparent piezoelectric elements; and
orthographic projections of the black matrixes onto the base substrate do not overlap with orthographic projections of the light-emitting elements onto the base substrate.

17. The touch display device according to claim 10, wherein the touch display panel further comprises:
a glass cover plate arranged above the touch structure.

18. The touch display device according to claim 10, wherein the material of the transparent piezoelectric elements is organic polyvinylidene fluoride and pigment materials.

19. A method for driving the touch display device, comprising the touch display panel according to claim 1, the method comprising:
supplying the first electrode layer and the second electrode layer respectively with a touch detection driving signal and a voltage signal;
receiving a sensed touch signal fed back by the first electrode layer or the second electrode layer after a user touches the touch display panel; and
determining the position of the touch by the user according to the sensed touch signal, or determining fingerprint information of the user at the position of the touch according to a variation of the sensed touch signal.
